(19) United States
(12) Patent Application Publication
(10) Pub. No.: US 2025/0201787 A1
(43) Pub. Date: Jun. 19, 2025

(54) APPARATUS AND METHODS FOR EMBEDDING DEEP TRENCH CAPACITOR (DTC) COMPONENTS IN A SUBSTRATE

(71) Applicant: Intel Corporation, Santa Clara, CA (US)

(72) Inventors: Marcel M. Said, Beaverton, OR (US); Tolga Acikalin, San Jose, CA (US); Soham Agarwal, Chandler, AZ (US); Benjamin T. Duong, Phoenix, AZ (US); Jeremy D. Ecton, Gilbert, AZ (US); Kari E. Hernandez, Phoenix, AZ (US); Brandon Christian Marin, Gilbert, AZ (US); Pratyush Mishra, Tempe, AZ (US); Pratyasha Mohapatra, Hillsboro, OR (US); Srinivas Venkata Ramanuja Pietambaram, Chandler, AZ (US)

(73) Assignee: Intel Corporation, Santa Clara, CA (US)

(21) Appl. No.: 18/544,408

(22) Filed: Dec. 18, 2023

(51) Int. Cl. H01L 25/16; H01L 25/00

(52) U.S. Cl. CPC H01L 25/16; H01L 25/50; H10D 1/68

(57) ABSTRACT

Apparatus and methods for embedding deep trench capacitors (DTCs) in a package substrate. The method includes fabricating an integrated circuit on a silicon substrate core and identifying a deep trench capacitor (DTC) component to integrate with the integrated circuit. A cavity is created in the silicon substrate core to accommodate the DTC component. The cavity extends therethrough, like a through-hole. A temporary carrier is attached to the silicon substrate to create a cavity floor. A gap magnitude is determined, which is a difference between the thickness of the silicon substrate core and the thickness of the DTC component. An epoxy material with a minimum bond line that matches the gap magnitude is selected and implemented to fill the gap in fabrication. The minimum bond line is controlled by selection of particles to use in the epoxy material.

### BACKGROUND

The demand for miniaturization of form factor and increased levels of integration for high performance are driving sophisticated component geometries in the semiconductor industry. In some scenarios, these components are created in a separate manufacturing process and later attached to (or embedded within) a substrate. One such example component is an embodiment of a capacitor referred to as a trench capacitor or a deep trench capacitor (DTC) component; the sophisticated geometry of DTCs enables an increased capacitance without also increasing a footprint. However, there are technical challenges to embedding components in substrates. Accordingly, continued improvements to apparatus with embedded DTC components and methods for making the same are desired.

### BRIEF DESCRIPTION OF THE DRAWINGS

FIG. 1 illustrates an example semiconductor package that implements at least one embedded DTC component, in accordance with various embodiments.

FIGS. 2-3 illustrate various stages of fabrication in a method for embedding a DTC component in a substrate, in accordance with various embodiments.

FIG. 4 is an exemplary method for embedding a DTC component in a substrate.

FIG. 5 is a top view of a wafer and dies that may have at least one embedded DTC component, in accordance with any of the embodiments disclosed herein.

FIG. 6 is a simplified cross-sectional side view showing an implementation of an integrated circuit on a die that may include various embodiments, in accordance with any of the embodiments disclosed herein.

FIG. 7 is a cross-sectional side view of a microelectronic assembly that may include any of the embodiments disclosed herein.

FIG. 8 is a block diagram of an example electrical device that may include any of the embodiments disclosed herein.

### DETAILED DESCRIPTION

The integration of multiple integrated circuit (IC) components in semiconductor packaging to meet the expectations of high-speed signaling often involves the technical challenge of relying on one or more embedded components. The embedded components may support finer pitches and/or more sophisticated geometries than the surrounding semiconductor substrate. However, there can be a thickness or height mismatch between the target component to embed and the surrounding semiconductor substrate or “core.”

With respect to embedded deep trench capacitors (DTCs), a proposed technical solution is to select a substrate thickness that has a thickness that matches that of the DTC component. In practice, changing the substrate thickness to accommodate the DTC thickness adversely results in limits on the mechanical properties of the core or substrate, such as total thickness variation, and coefficient of thermal expansion (CTE).

Embodiments described herein provide a technical solution to these technical challenges in the form of apparatus and methods for embedding deep trench capacitors in a core or substrate. Such an approach can be used in semiconductor packages and assemblies that combine integrated circuitry, such as a central processing unit (CPU) with embedded components such as deep trench capacitors (DTCs). Embodiments enable embedding components such as DTCs in substrates that are thicker than the thickness of the DTC component.

Advantageously, embodiments enable the silicon substrate or core to be fabricated to an optimal thickness for a respective integrated circuit, and further enable that multiple different components can be embedded therewith, without altering the core or substrate thickness. During assembly, a cavity is created in the surface of the substrate, and a non-conductive material, such as an epoxy material, is placed in the cavity, and the DTC component is placed on the epoxy. The epoxy material has particles therein that remedy the thickness mismatch. These concepts are developed in more detail below.

Example embodiments are hereinafter described in conjunction with the following drawing figures, wherein like numerals denote like elements. Figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

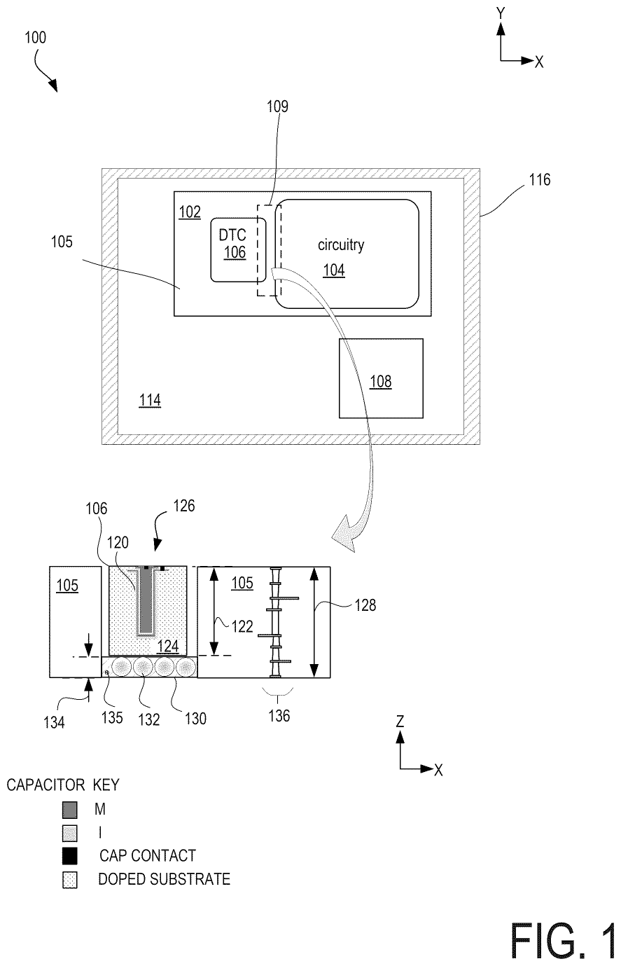

The non-limiting example in FIG. 1 is a semiconductor package 100 (alternatively referred to as a package assembly) having a first integrated circuit die 102 comprising a “core” or substrate 105 having therein an integrated circuit, indicated generally with integrated circuitry 104. In various embodiments, the substrate 105 may comprise silicon (Si), Si on insulator, any II-VI and III-V material, fused quartz or glass, etc. The core also has therein at least one embedded component. In various embodiments, the embedded component is a trench capacitor, or a deep trench capacitor component (DTC component 106). The integrated circuitry 104 and DTC component 106 can be in electronic communication with each other, as may occur generally in region 109. While the integrated circuitry 104 is depicted as occupying an area that is discrete from, and to the right of, the DTC component 106 in the substrate 105 (on the page), in practice, the active and passive components that make up the integrated circuitry 104 may be distributed around the substrate 105 and around the area demarked for the DTC component 106 (hence, the component or DTC component 106 is referred to as “embedded”). In some embodiments, the substrate 105 and integrated circuitry 104 are referred to as an apparatus and as at least part of a substrate package.

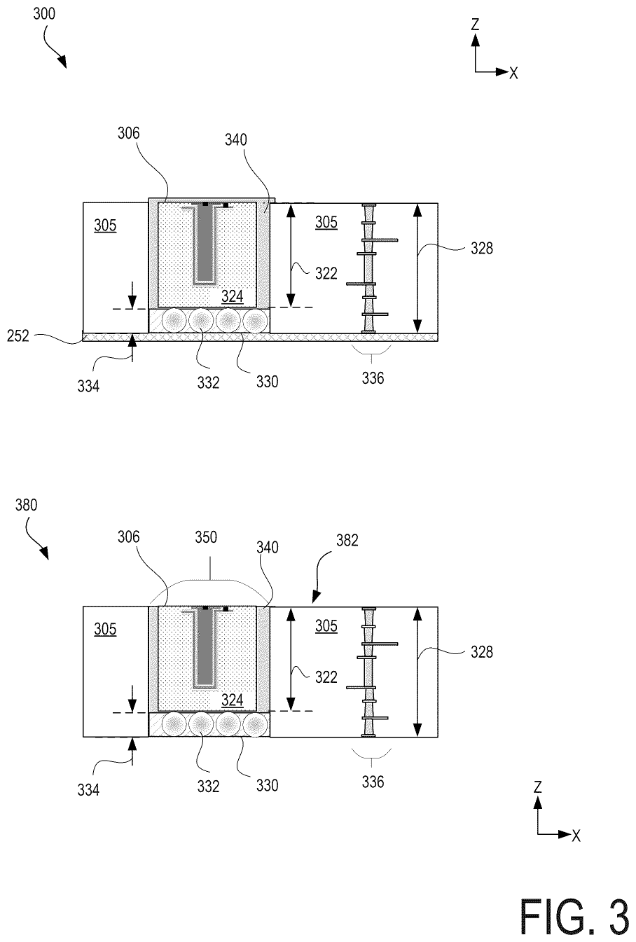

As depicted at the simplified zoomed-in view indicated with the cartoon arrow, the “core” or substrate of the IC die 102 has a core thickness 128, an upper surface (FIG. 3, 382) and a lower surface. The embedded component is oriented such that its upper surface is coplanar with the upper surface of the substrate 105. Accordingly, the exemplary embodiment of the DTC component 106 is in the substrate with an upper surface that is flush with/continuous with the upper surface of the substrate 105 in the figure. The embedded component (e.g., DTC component 106) has a respective substrate, with a second thickness (thickness 122) that is less than the first thickness, thereby creating a gap 134.

In the cross-sectional view illustrated, the embedded component is a capacitor component. The capacitor component comprises a trench formed in the second substrate, denoted trench structure 120, and the second substrate may be a doped substrate 124 (generally a n-doped substrate). The trench structure 120 is achieved with fabrication of a capacitor in a trench formed in the upper surface 126 of the doped substrate 124. The trenches can have aspect ratios (AR, the height to width) of 10 or greater; in some embodiments, the trenches have ARs of >40. Therefore, regardless of the shape of the trench (e.g., from a cross-sectional view-V-shapes, trapezoids, conical, etc.), the trench walls contribute to the bulk of the surface area of the plates or layers that comprise the trench capacitor. In practice, the trench walls may be sloped inward, although they are illustrated as straight walls for simplicity.

The capacitor in the trench structure 120 may comprise a bottom plate or layer of metal (M) that conforms to the shape of the trench and has a M layer thickness in a range of 50 to 400 angstroms, followed by a layer of an insulating material (I) that is in a range of 50-1000 angstroms thick, followed by a top plate or layer of metal (M). The insulating material (I) conforms to the bottom plate or layer of metal, following it into the trench and out, as illustrated, and the top plate or layer of metal (M) conforms to the insulating material (I), following it into the trench and out, as shown. In various embodiments, the bottom plate of metal and the top plate of metal comprise the same metal, and substantially the same thickness. Accordingly, the trench structure 120 may be described as a MIM structure, wherein the M represents a metal, and the I represents an insulator material. In various embodiments, the M can comprise multiple layers of TiN or Ir/IrO₂, Ru/RuO₂, or other metals, and the I can be Al₂O₃, aluminum oxide or other dielectrics such as, TiO₂, HfO₂, HZO, etc. In various embodiments, the I can comprise multiple layers of dielectric. The doped substrate may be n-doped silicon and may function as a metal layer.

As illustrated, in a cross-sectional view, the capacitor in the trench structure 120 can be described as having two metal plates that are substantially orthogonal to the upper surface 126 and conform to a trench formed in an upper surface of the doped substrate 124. While just one trench capacitor is shown for simplicity, those with skill in the art will recognize that in various embodiments, another insulating layer may be placed conformally over the top plate of metal, and a second MIM capacitor may be overlaid conformally in the trench, and so on, thereby stacking multiple capacitors in a single trench. Moreover, in practice, the embedded component DTC component 106 may have a plurality of similar trenches.

In the non-limiting example, the DTC component 106/206/306 is exposed at the upper surface (E.g., FIG. 3, upper surface 382) where it has one or more contacts, as illustrated, and extends orthogonally downward in the substrate therefrom. The conductive contacts are to electrically connect capacitors from the DTC component 106 to integrated circuitry 104. Additionally, a plurality of conductive contacts may be located on at least the upper surface of the substrate 105/205/305 to electrically connect the substrate package with other die and memory devices external to the substrate package.

The core thickness 128 of the substrate 105 can vary in a range of 200 microns+/−50 microns to 1 millimeter+/−50 microns. Although the embedded DTC component 106 can be realized in a variety of different geometries, various embodiments can be characterized or described as having a thickness (thickness 122) of 650 microns plus or minus 20%. Accordingly, the gap 134/234/334 (with a magnitude measured as a height or thickness, as illustrated) is realized between a lower surface of the substrate 105/205/305 and a lower surface of the DTC component 106/206/306. The gap 134 has a magnitude that is a difference measured between the core thickness 128 (also, substrate 105 thickness) and the DTC component 106 thickness 122. Embodiments propose a method to infill the gap 134 with an application-specific insulating or non-conductive material; specifically, embodiments employ an insulating material or epoxy material 130 comprising size-controlled target particles 132 selected to match the gap 134 for a given application.

The target particles are selected based on their dimensions and the minimum bond line that they impart to the non-conductive or epoxy material that includes them. The minimum bond line is the minimum thickness to which the epoxy material can be compressed. The epoxy material with target particles is selected to have a minimum bond line that is proportional to or substantially equal to the gap 134. Described differently, the diameter of the target particles 132 used in the non-conductive or epoxy material 130 is selected to be proportional to or substantially equal to the gap 134 measurement.

While the images are not drawn to scale, it is intentional in the illustrated embodiment that there is only one monolayer of target particles 132 in the epoxy material 130, but that there may be other particles present in the insulating or epoxy material, those other particles are generally represented with particle 135, which is smaller than the target particles 132. In various embodiments, about 90% of all of the particles present in the non-conductive or epoxy material 130 are target particles 132 with the same size as each other, as illustrated; further, the height/thickness/diameter of the target particles (depending on how they are shaped and measured) is substantially the same as the gap 334 magnitude, (wherein substantially here means+/−20%).

Therefore, to identify embodiments of this disclosure, one would look at a portion of a substrate package or substrate 105, e.g., using SEM or TEM (transmission electron microscopy) and identify a region (e.g., region 109) in the substrate 105 in which there is an embedded component or structure, such as the trench structure 120 of embedded DTC component 106 near integrated circuitry 104 (represented as column 136) in which the thickness of the core or substrate 105 is greater than the thickness of the substrate of the embedded component. Embodiments implementing the described apparatus and methods have a non-conductive or epoxy material 130 under the embedded component that comprises one or more target particles 132, the target particles 132 can be identified because they are proportional to or substantially equal to the magnitude of the gap 134 in thickness between the core or substrate 105 and the thickness of the embedded component. The target particles 132 are located adjacent to the bottom surface of the embedded component and the bottom surface of the substrate 105 or core.

Various embodiments of these apparatus and methods can be found in more complex systems and assemblies. For example, the example semiconductor package 100 illustrates a multi-die assembly including another integrated circuit die 108, in which the dies (102/108) are attached to a package substrate 114. The first die 102 and/or the second die 108 may be an electronic integrated circuit die (EIC) or a photonic integrated circuit die (PIC). In various embodiments, the IC die 102 is a central processing unit (CPU) or graphics processing unit (GPU). In some embodiments, the second die 108 is a memory device.

In a package assembly and/or device embodiment, the substrate 114 may further be attached to a printed circuit board (PCB); and in further embodiments, the package assembly may include additional IC die and one or more memory devices attached to the PCB. As may be appreciated, this arrangement of die is just one example embodiment. In various embodiments, such as when implemented in a packaged assembly or a device, the die in the semiconductor package 100 may be overmolded with an encapsulant 116. The encapsulant 116 can comprise a molding compound, dielectric materials, metal, ceramic, plastic, or a combination thereof.

Additionally, a thermal management solution (not shown) comprising a cooling component such as a vapor chamber, heat pipe, heat sink, or liquid-cooled cold plate may be attached to a semiconductor package 100. As part of a thermal management solution, a thermal conduction layer interface material (TIM) may be located over the IC die 102, and potentially also over the IC die 108. The TIM can be any suitable material, such as a silver particle-filled thermal compound, thermal grease, phase change materials, indium foils, or graphite sheets. The thermal management solution can be a conformal solution that accommodates differences in heights of the integrated circuit dies for which the thermal management solution provides cooling. For example, a thermal management solution can comprise a substantially planar cooling component with TIMs of varying thickness between the cooling component and the integrated circuit dies. In another example, the cooling component is non-planar, and the profile of the cooling component can vary with the thickness of the integrated circuit dies for which the cooling component provides cooling. In such embodiments, the TIM can be of substantially uniform thickness between the cooling component and the integrated circuit dies of varying thicknesses. Thermal management solutions can also include an integrated heat spreader.

Those with skill in the art will appreciate that the substrate 105 may be a silicon substrate and generally comprises multiple redistribution layers (RDL) interleaved with dielectric material, to realize the integrated circuitry 104; in the simplified illustrations, the integrated circuitry 104 is generally represented with the column 136 of vias and RDLs.

As used herein, redistribution layers (RDL), indicated generally with the RDL column 136, include metal or conductive traces or interconnects, generally within dielectric layers, that connect or provide electrical paths between one region in a semiconductor package to another region and are sufficient for electrical communication and/or for supplying power and ground. The RDL of the substrate 105 may implement a larger, “core geometry,” such as a 9/12 geometry (meaning a conductive trace width of 9 microns and a spacing of 12 microns). Embodiments of the embedded DTC component 106 can comprise the same trace or RDL materials and line widths as the RDL in the integrated circuitry 104 of the IC die 102; however, this is not necessary, as the DTC component 106 can be manufactured in a separate process flow.

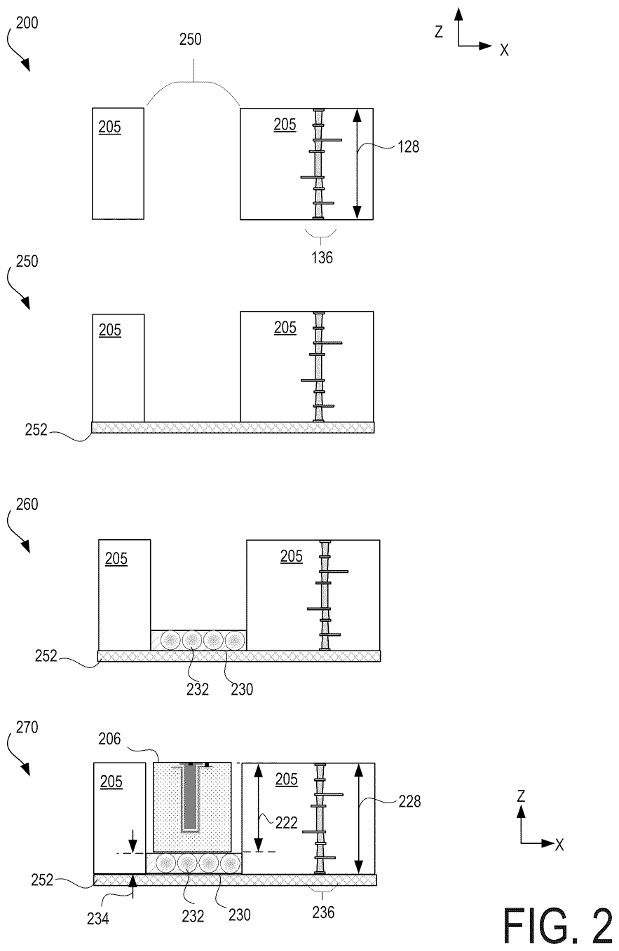

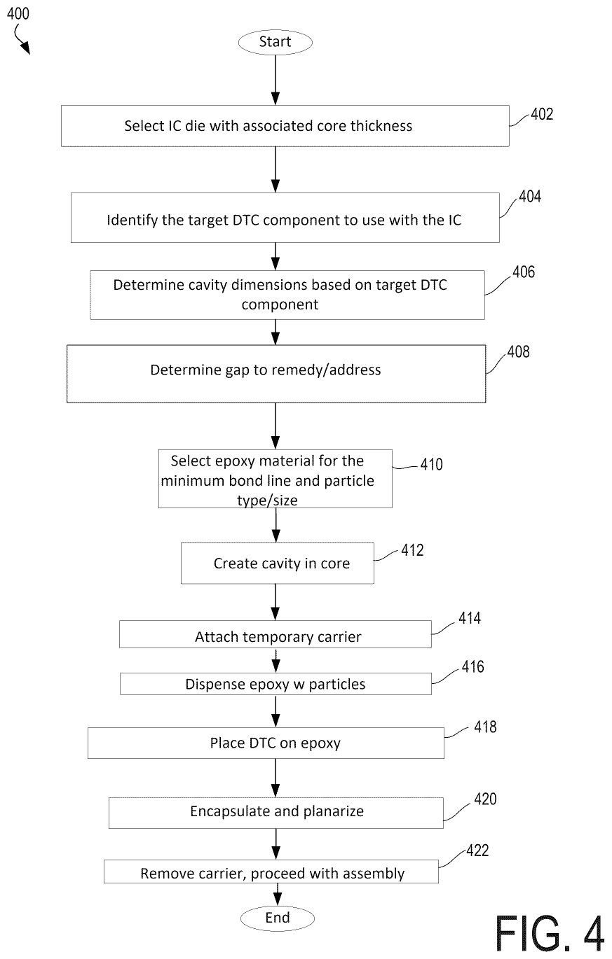

FIGS. 2-4 are described together below. FIGS. 2-3 illustrate various stages of fabrication in a method for embedding a DTC component in a substrate, in accordance with various embodiments, and FIG. 4 is an exemplary method for embedding a DTC component in a substrate.

The “core” or substrate 205/305 reflects the IC die 102 for which the DTC is to be embedded. At 402, the IC die with its associated “core” thickness is selected to have the DTC embedded therein. As mentioned, the substrate 205/305 may comprise dielectric layers that include respective redistribution layers (RDL); the dielectric layers are substantially coplanar with an upper surface of the silicon substrate. The dielectric layers can comprise a suitable nitride or oxide, such as silicon dioxide (SiO₂), carbon-doped silicon dioxide, fluorine-doped silicon dioxide, hydrogen-doped silicon dioxide, or silicon nitride.

In various embodiments, the dielectric material can include a suitable nitride or oxide, such as silicon dioxide (SiO₂), carbon-doped silicon dioxide (C doped SiO2, also known as CDO or organosilicate glass, which is a material that comprises silicon, oxygen, and carbon), fluorine-doped silicon dioxide (F-doped SiO2, also known as fluorosilicate glass, which is a material that comprises fluorine, silicon, and oxygen), hydrogen-doped silicon dioxide (H-doped SiO2, which is a material that comprises silicon, oxygen, and hydrogen). In some embodiments, a dielectric layer comprises a photo-imageable dielectric (PID). In some embodiments, the dielectric layer comprises an Ajinomoto Build-Up film (often referred to as ABF), which is a material that comprises an organic resin matrix with different types of fillers (for example, silica fillers of different sizes, or hollow fillers of different sizes) to control the coefficient of thermal expansion (CTE) and/or electrical properties (e.g., the dielectric constant (Dk), and/or dissipation factor (insertion loss) (Df)).

The RDL may comprise a metal (e.g., copper, aluminum, nickel, cobalt, iron, tin, gold, silver, or combinations thereof) or another suitable conductive material. The RDL may have a thickness (measured in the Z direction in the figure) from about 1 micron to 10 microns. In various embodiments, the RDL may be substantially 5 microns.

At 404 the target DTC component is identified, at 406 the cavity 250/350 dimensions are determined, based on the dimensions of the target DTC component. As alluded to above, the thickness of the DTC component 106/206/306 is a function of at least the technology used for fabrication and the number of capacitors stacked in the trench (e.g., in a MIM DTC).

At 408, the gap to be remedied or filled is determined, based on the thickness of the target DTC component. Specifically, at 408 the magnitude of a gap 134 defined as a difference between the thickness of the silicon substrate and the thickness of the DTC component is determined. At 410, an epoxy material 230/330 is selected with a minimum bond line that matches the gap 134 plus or minus 20% (i.e., with a minimum bond line that is proportional to or substantially equal to the magnitude of the gap 134). As used herein, “epoxy material” may include epoxy resin, a fiberglass-reinforced epoxy resin, an epoxy resin with inorganic fillers, a ceramic material, or a polymer material such as polyimide. In various embodiments, this means selecting an epoxy and selecting target particles/particle types such that the height/thickness/diameter of the target particles (depending on the measurement made) matches the gap.

In other embodiments, at 410 a means for gap filling is selected to remedy the gap, wherein the epoxy material 230/330 is one of multiple possible means for gap filling.

In various embodiments, the target particles can have a variety of types and sizes. The target particle type may be any kind of oxide. In some embodiments, the target particles may be aluminum oxide (Al₂O₃). Aluminum oxide is thermally conductive, but in other embodiments, the target particle type is not thermally conductive, such as with target particles that comprise silica or target particles that comprise boron nitride. Moreover, those with skill in the art will appreciate that the size of the aluminum oxide particles can be controlled by various means, such that two epoxy materials that each have aluminum oxide particles may have different sized aluminum oxide particles.

The largest particles in the epoxy material 130 determine the minimum bond line, which is the what is selected for in these embodiments. In various embodiments, the target particles 132 are the largest particles, with a diameter of 100 nanometers (nm) plus or minus 20%.

In other embodiments, the diameter of the target particles 132 is in a range of 3 nm (plus or minus 20%) to 500 nm (plus or minus 20%.)

At 412 (embodiment 200), the cavity 250/350 is created in the core silicon substrate 205/305. In various embodiments, this is achieved by removing substrate material. In various embodiments, this means removing dielectric material. A laser ablation process or dry etch process may be used to remove the dielectric material and create the cavity 250/350. The cavity 250/350 circumference and/or diameter reflects the determinations made for the target DTC component, and extends through the core silicon substrate 205/305, as illustrated. Although this appears, in the two-dimensional illustration, to cut the silicon substrate 205/305 into two, those with skill in the art will recognize that, in three dimensions, this is a through-hole, and the “core” or silicon substrate 205/305 remains as a single piece. Moreover, although the figures illustrate the cavity as having perpendicular walls, this is to simplify drawings. In practice, the cavity walls appear angled inward traveling from the upper surface to the lower surface (e.g., on the page), where the carrier 252 is attached.

At 414 (embodiment 250), a temporary carrier 252 is attached to a lower surface of the silicon substrate 205/305. In various embodiments, the carrier 252 comprises glass (as used herein, glass can be an alkali-free alkaline earth boro-aluminosicilate glass, such as a glass comprising aluminum, oxygen, boron, silicon, and an alkaline-earth metal (e.g., beryllium, magnesium, calcium, strontium, barium, radium, such as a glass comprising SiO2, Al2O3, B2O3, and MgO), or a photosensitive glass (photomachineable or photostructurable glass).

At 416 (embodiment 260) the means for remedying the gap 134 is employed. Accordingly, in various embodiments, at 416, the epoxy material 230/330 with target particles 232/332 therein (that was selected at 410) is dispensed in the cavity 250/350. At 418 (embodiment 270), the DTC component 206/306 is placed in the cavity 250/350 and the epoxy material 230/330 is compressed to its minimum bond line 234/334.

At 420 (embodiment 300) the DTC component 206/306 can be encapsulated with a mold compound (340) and planarized (the apparatus of embodiment 380). The mold compound is a non-conductive material, and it can be found sandwiched between (and/or adjacent to) the substrate 105/205/305 and the DTC component 106/206/306. At 422, the carrier can be removed, and further fabrication and assembly steps may be performed, such as adding solder bumps, singulation, pick and place, etc.

Thus, various apparatus with an embedded DTC component in a substrate and methods for making the same have been described. The following description provides additional details and context for various die and various package assembly and device configurations that can be created based on or using the provided embodiments.

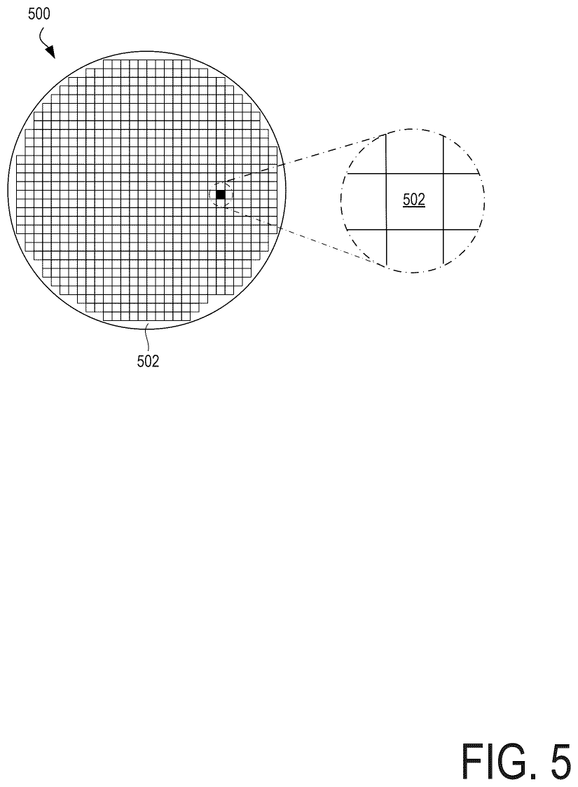

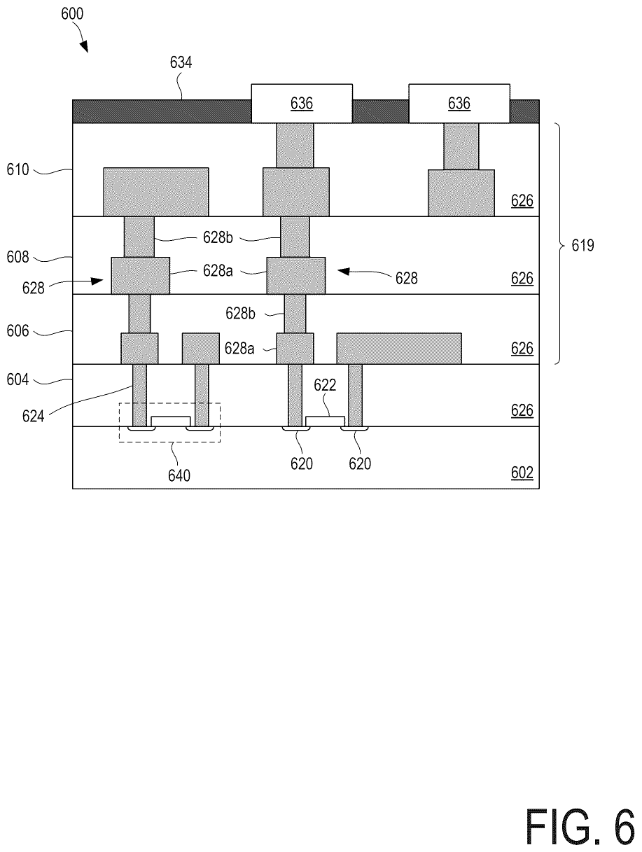

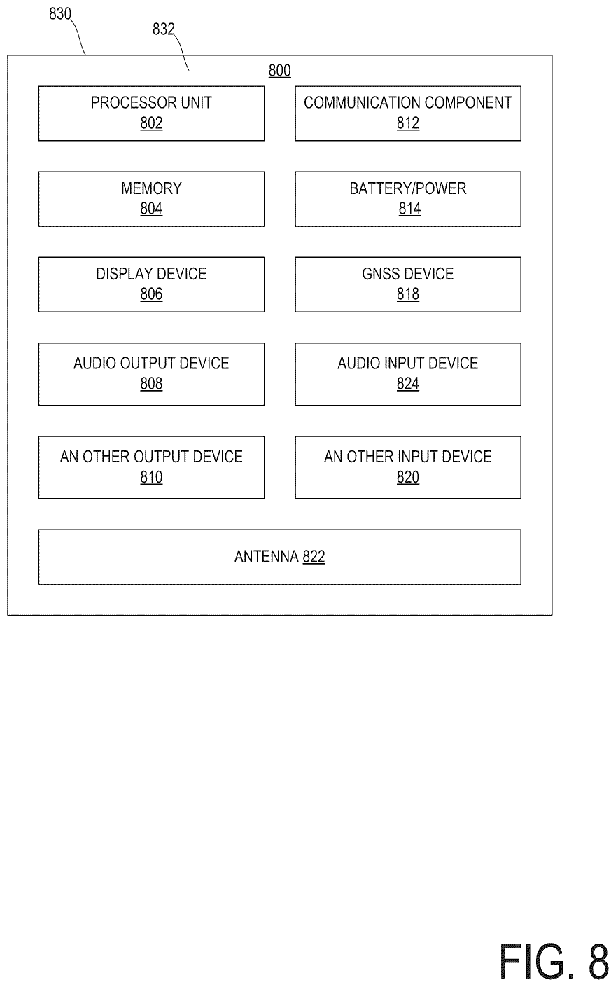

FIG. 5 is a top view of a wafer 500 and dies 502 that may be include any of the embodiments disclosed herein. The wafer 500 may be composed of semiconductor material and may include one or more dies 502 formed on a surface of the wafer 500. After the fabrication of the integrated circuit components on the wafer 500 is complete, the wafer 500 may undergo a singulation process in which the dies 502 are separated from one another to provide discrete “chips” or destined for a packaged integrated circuit component. The individual dies 502, comprising an integrated circuit component, may include one or more transistors (e.g., some of the transistors 640 of FIG. 6, discussed below), supporting circuitry to route electrical signals to the transistors, passive components (e.g., signal traces, resistors, capacitors, or inductors), and/or any other integrated circuit components. In some embodiments, the wafer 500 or the die 502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 502. For example, a memory array formed by multiple memory devices may be formed on a same die 502 as a processor unit (e.g., the processor unit 802 of FIG. 8) or other logic that is configured to store information in the memory devices or execute instructions stored in the memory array. In some embodiments, a die 502 may be attached to a wafer 500 that includes other die, and the wafer 500 is subsequently singulated, this manufacturing procedure is referred to as a die-to-wafer assembly technique.

FIG. 6 is a cross-sectional side view of an integrated circuit 600 that may be included in any of the embodiments disclosed herein. One or more of the integrated circuits 600 may be included in one or more dies 502 (FIG. 5). The integrated circuit 600 may be formed on a die substrate 602 (e.g., the wafer 500 of FIG. 5) and may be included in a dic (e.g., the die 502 of FIG. 5).

The die substrate 602 may be a semiconductor substrate composed of semiconductor material systems including, for example, n-type or p-type materials systems (or a combination of both). The die substrate 602 may include, for example, a crystalline substrate formed using a bulk silicon or a silicon-on-insulator (SOI) substructure. In some embodiments, the die substrate 602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 602. Although a few examples of materials from which the die substrate 602 may be formed are described here, any material that may serve as a foundation for an integrated circuit 600 may be used. The die substrate 602 may be part of a singulated die (e.g., the dies 502 of FIG. 5) or a wafer (e.g., the wafer 500 of FIG. 5).

The integrated circuit 600 may include one or more device layers 604 disposed on the die substrate 602. The device layer 604 may include features of one or more transistors 640 (e.g., metal oxide semiconductor field-effect transistors (MOSFETs)) formed on the die substrate 602. The transistors 640 may include, for example, one or more source and/or drain (S/D) regions 620, a gate 622 to control current flow between the S/D regions 620, and one or more S/D contacts 624 to route electrical signals to/from the S/D regions 620.

The gate 622 may be formed of at least two layers, a gate dielectric, and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 640 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 640 along the source-channel-drain direction, the gate electrode may comprise a U-shaped structure that includes a bottom portion substantially parallel to the surface of the die substrate 602 and two sidewall portions that are substantially perpendicular to the top surface of the die substrate 602. In other embodiments, at least one of the metal layers that form the gate electrode may simply be a planar layer that is substantially parallel to the top surface of the die substrate 602 and does not include sidewall portions substantially perpendicular to the top surface of the die substrate 602. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and include deposition and etching processes. In some embodiments, a plurality of spacer pairs may be used; for instance, two pairs, three pairs, or four pairs of sidewall spacers may be formed on opposing sides of the gate stack.

The S/D regions 620 may be formed within the die substrate 602 adjacent to the gate 622 of individual transistors 640. The S/D regions 620 may be formed using an implantation/diffusion process or an etching/deposition process, for example. In the former process, dopants such as boron, aluminum, antimony, phosphorous, or arsenic may be ion-implanted into the die substrate 602 to form the S/D regions 620. An annealing process that activates the dopants and causes them to diffuse farther into the die substrate 602 may follow the ion-implantation process. In the latter process, the die substrate 602 may first be etched to form recesses at the locations of the S/D regions 620. An epitaxial deposition process may then be conducted to fill the recesses with material that is used to fabricate the S/D regions 620. In some implementations, the S/D regions 620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 620 may be formed using one or more alternate semiconductor materials such as germanium or a group III-V material or alloy. In further embodiments, one or more layers of metal and/or metal alloys may be used to form the S/D regions 620.

Electrical signals, such as power and/or input/output (I/O) signals, may be routed to and/or from the devices (e.g., transistors 640) of the device layer 604 through one or more interconnect layers disposed on the device layer 604 (illustrated in FIG. 6 as interconnect layers 606-610). For example, electrically conductive features of the device layer 604 (e.g., the gate 622 and the S/D contacts 624) may be electrically coupled with the interconnect structures 628 of the interconnect layers 606-610. The one or more interconnect layers 606-610 may form a metallization stack (also referred to as an “ILD stack”) 619 of the integrated circuit 600.

The interconnect structures 628 may be arranged within the interconnect layers 606-610 to route electrical signals according to a wide variety of designs; in particular, the arrangement is not limited to the particular configuration of interconnect structures 628 depicted in FIG. 6. Although a particular number of interconnect layers 606-610 is depicted in FIG. 6, embodiments of the present disclosure include integrated circuits having more or fewer interconnect layers than depicted.

In some embodiments, the interconnect structures 628 may include lines 628a and/or vias 628b filled with an electrically conductive material such as a metal. The lines 628a may be arranged to route electrical signals in a direction of a plane that is substantially parallel with a surface of the die substrate 602 upon which the device layer 604 is formed. For example, the lines 628a may route electrical signals in a direction in and out of the page and/or in a direction across the page. The vias 628b may be arranged to route electrical signals in a direction of a plane that is substantially perpendicular to the surface of the die substrate 602 upon which the device layer 604 is formed. In some embodiments, the vias 628b may electrically couple lines 628a of different interconnect layers 606-610 together.

The interconnect layers 606-610 may include a dielectric material 626 disposed between the interconnect structures 628, as shown in FIG. 6. In some embodiments, dielectric material 626 disposed between the interconnect structures 628 in different ones of the interconnect layers 606-610 may have different compositions; in other embodiments, the composition of the dielectric material 626 between different interconnect layers 606-610 may be the same. The device layer 604 may include a dielectric material 626 disposed between the transistors 640 and a bottom layer of the metallization stack as well. The dielectric material 626 included in the device layer 604 may have a different composition than the dielectric material 626 included in the interconnect layers 606-610; in other embodiments, the composition of the dielectric material 626 in the device layer 604 may be the same as a dielectric material 626 included in any one of the interconnect layers 606-610.

A first interconnect layer 606 (referred to as Metal 1 or “M1”) may be formed directly on the device layer 604. In some embodiments, the first interconnect layer 606 may include lines 628a and/or vias 628b, as shown. The lines 628a of the first interconnect layer 606 may be coupled with contacts (e.g., the S/D contacts 624) of the device layer 604. The vias 628b of the first interconnect layer 606 may be coupled with the lines 628a of a second interconnect layer 608.

The second interconnect layer 608 (referred to as Metal 2 or “M2”) may be formed directly on the first interconnect layer 606. In some embodiments, the second interconnect layer 608 may include via 628b to couple the lines of the interconnect structures 628 of the second interconnect layer 608 with the lines 628a of a third interconnect layer 610. Although the lines 628a and the vias 628b are structurally delineated with a line within individual interconnect layers for the sake of clarity, the lines 628a and the vias 628b may be structurally and/or materially contiguous (e.g., simultaneously filled during a dual-damascene process) in some embodiments.

The third interconnect layer 610 (referred to as Metal 3 or “M3”) (and additional interconnect layers, as desired) may be formed in succession on the second interconnect layer 608 according to similar techniques and configurations described in connection with the second interconnect layer 608 or the first interconnect layer 606. In some embodiments, the interconnect layers that are “higher up” in the metallization stack 619 in the integrated circuit 600 (i.e., farther away from the device layer 604) may be thicker that the interconnect layers that are lower in the metallization stack 619, with lines 628a and vias 628b in the higher interconnect layers being thicker than those in the lower interconnect layers.

The integrated circuit 600 may include a solder resist material 634 (e.g., polyimide or similar material) and one or more conductive contacts 636 formed on the interconnect layers 606-610. In FIG. 6, the conductive contacts 636 are illustrated as taking the form of bond pads. The conductive contacts 636 may be electrically coupled with the interconnect structures 628 and configured to route the electrical signals of the transistor(s) 640 to external devices. For example, solder bonds may be formed on the one or more conductive contacts 636 to mechanically and/or electrically couple an integrated circuit die including the integrated circuit 600 with another component (e.g., a printed circuit board). The integrated circuit 600 may include additional or alternate structures to route the electrical signals from the interconnect layers 606-610; for example, the conductive contacts 636 may include other analogous features (e.g., posts) that route the electrical signals to external components.

In some embodiments in which the integrated circuit 600 is a double-sided die, the integrated circuit 600 may include another metallization stack (not shown) on the opposite side of the device layer(s) 604. This metallization stack may include multiple interconnect layers as discussed above with reference to the interconnect layers 606-610, to provide electrically conductive paths (e.g., including conductive lines and vias) between the device layer(s) 604 and additional conductive contacts (not shown) on the opposite side of the integrated circuit 600 from the conductive contacts 636.

In other embodiments in which the integrated circuit 600 is a double-sided die, the integrated circuit 600 may include one or more through-silicon vias (TSVs) through the die substrate 602; these TSVs may make contact with the device layer(s) 604, and may provide electrically conductive paths between the device layer(s) 604 and additional conductive contacts (not shown) on the opposite side of the integrated circuit 600 from the conductive contacts 636. In some embodiments, TSVs extending through the substrate can be used for routing power and ground signals from conductive contacts on the opposite side of the integrated circuit 600 from the conductive contacts 636 to the transistors 640 and any other components integrated into the die with the integrated circuit 600, and the metallization stack 619 can be used to route I/O signals from the conductive contacts 636 to transistors 640 and any other components integrated into the die with the integrated circuit 600.

Multiple integrated circuits 600 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

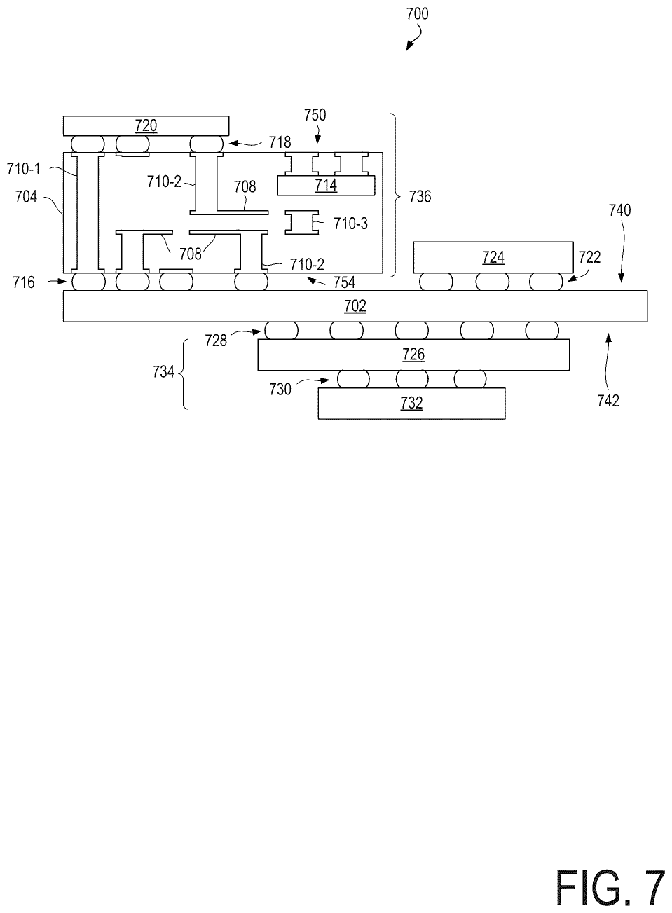

FIG. 7 is a cross-sectional side view of a microelectronic assembly 700 that may include any of the embodiments disclosed herein. The microelectronic assembly 700 includes multiple integrated circuit components disposed on a circuit board 702 (which may be a motherboard, system board, mainboard, etc.). The microelectronic assembly 700 may include components disposed on a first face 740 of the circuit board 702 and an opposing second face 742 of the circuit board 702; generally, components may be disposed on one or both faces 740 and 742.

In some embodiments, the circuit board 702 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 702. In other embodiments, the circuit board 702 may be a non-PCB substrate. The microelectronic assembly 700 illustrated in FIG. 7 includes a package-on-interposer structure 736 coupled to the first face 740 of the circuit board 702 by coupling components 716. The coupling components 716 may electrically and mechanically couple the package-on-interposer structure 736 to the circuit board 702, and may include solder balls (as shown in FIG. 7), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 736 may include an integrated circuit component 720 coupled to an interposer 704 by coupling components 718. The coupling components 718 may take any suitable form for the application, such as the forms discussed above with reference to the coupling components 716. Although a single integrated circuit component 720 is shown in FIG. 7, multiple integrated circuit components may be coupled to the interposer 704; indeed, additional interposers may be coupled to the interposer 704. The interposer 704 may provide an intervening substrate used to bridge the circuit board 702 and the integrated circuit component 720.

The integrated circuit component 720 may be a packaged or unpackaged integrated circuit component that includes one or more integrated circuit dies (e.g., the die 502 of FIG. 5, the integrated circuit 600 of FIG. 6) and/or one or more other suitable components.

The unpackaged integrated circuit component 720 comprises solder bumps attached to contacts on the die. The solder bumps allow the die to be directly attached to the interposer 704. In embodiments where the integrated circuit component 720 comprises multiple integrated circuit die, the dies can be of the same type (a homogeneous multi-die integrated circuit component) or of two or more different types (a heterogeneous multi-die integrated circuit component). In addition to comprising one or more processor units, the integrated circuit component 720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate, or combinations thereof. A packaged multi-die integrated circuit component can be referred to as a multi-chip package (MCP) or multi-chip module (MCM).

The interposer 704 may spread connections to a wider pitch or reroute a connection to a different connection. For example, the interposer 704 may couple the integrated circuit component 720 to a set of ball grid array (BGA) conductive contacts of the coupling components 716 for coupling to the circuit board 702. In the embodiment illustrated in FIG. 7, the integrated circuit component 720 and the circuit board 702 are attached to opposing sides of the interposer 704; in other embodiments, the integrated circuit component 720 and the circuit board 702 may be attached to a same side of the interposer 704. In some embodiments, three or more components may be interconnected by way of the interposer 704.

In some embodiments, the interposer 704 may be formed as a PCB, including multiple metal layers separated from one another by layers of dielectric material and interconnected by electrically conductive vias. In some embodiments, the interposer 704 may be formed of an epoxy resin, a fiberglass-reinforced epoxy resin, an epoxy resin with inorganic fillers, a ceramic material, or a polymer material such as polyimide. In some embodiments, the interposer 704 may be formed of alternate rigid or flexible materials that may include the same materials described above for use in a semiconductor substrate, such as silicon, germanium, and other group III-V and group IV materials. The interposer 704 may include metal interconnects 708 and vias 710, including but not limited to through hole vias 710-1 (that extend from a first face 750 of the interposer 704 to a second face 754 of the interposer 704), blind vias 710-2 (that extend from the first or second faces 750 or 754 of the interposer 704 to an internal metal layer), and buried vias 710-3 (that connect internal metal layers).

In some embodiments, the interposer 704 can comprise a silicon interposer. Through-silicon vias (TSV) extending through the silicon interposer can connect connections on the first face of a silicon interposer to an opposing second face of the silicon interposer. In some embodiments, an interposer 704 comprising a silicon interposer can further comprise one or more routing layers to route connections on a first face of the interposer 704 to an opposing second face of the interposer 704.

The interposer 704 may further include embedded devices 714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 704. The package-on-interposer structure 736 may take the form of any of the package-on-interposer structures known in the art.

The integrated circuit assembly 700 may include an integrated circuit component 724 coupled to the first face 740 of the circuit board 702 by coupling components 722. The coupling components 722 may take the form of any of the embodiments discussed above with reference to the coupling components 716, and the integrated circuit component 724 may take the form of any of the embodiments discussed above with reference to the integrated circuit component 720.

The integrated circuit assembly 700 illustrated in FIG. 7 includes a package-on-package structure 734 coupled to the second face 742 of the circuit board 702 by coupling components 728. The package-on-package structure 734 may include an integrated circuit component 726 and an integrated circuit component 732 coupled together by coupling components 730 such that the integrated circuit component 726 is disposed between the circuit board 702 and the integrated circuit component 732. The coupling components 728 and 730 may take the form of any of the embodiments of the coupling components 716 discussed above, and the integrated circuit components 726 and 732 may take the form of any of the embodiments of the integrated circuit component 720 discussed above. The package-on-package structure 734 may be configured in accordance with any of the package-on-package structures known in the art.

FIG. 8 is a block diagram of an example electrical device 800 that may include one or more of the embodiments disclosed herein. For example, any suitable ones of the components of the electrical device 800 may include one or more of the microelectronic assemblies 700, integrated circuit components 720, integrated circuits 600, integrated circuit dies 502, or structures disclosed herein; in various embodiments, the components are attached to a printed circuit board or motherboard 832. A number of components are illustrated in FIG. 8 as included in the electrical device 800, but any one or more of these components may be omitted or duplicated, as suitable for the application. In some embodiments, some or all the components included in the electrical device 800 may be attached to one or more motherboards, mainboards, printed circuit boards, or system boards. In some embodiments, one or more of these components are fabricated onto a single system-on-a-chip (SoC) die. In various embodiments, the electrical device 3000 is enclosed by, or integrated with, a housing.

Additionally, in various embodiments, the electrical device 800 may not include one or more of the components illustrated in FIG. 8, but the electrical device 800 may include interface circuitry for coupling to the one or more components. For example, the electrical device 800 may not include a display device 806, but may include display device interface circuitry (e.g., a connector and driver circuitry) to which a display device 806 may be coupled. In another set of examples, the electrical device 800 may not include an audio input device 824 or an audio output device 808, but may include audio input or output device interface circuitry (e.g., connectors and supporting circuitry) to which an audio input device 824 or audio output device 808 may be coupled.

The electrical device 800 may include one or more processor units 802 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 802 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 800 may include a memory 804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 804 may include memory that is located on the same integrated circuit die as the processor unit 802. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 800 can comprise one or more processor units 802 that are heterogeneous or asymmetric to another processor unit 802 in the electrical device 800. There can be a variety of differences between the processor units 802 in a system in terms of a spectrum of metrics of merit including architectural, microarchitectural, thermal, power consumption characteristics, and the like. These differences can effectively manifest themselves as asymmetry and heterogeneity among the processor units 802 in the electrical device 800.

In some embodiments, the electrical device 800 may include a communication component 812 (e.g., one or more communication components). For example, the communication component 812 can manage wireless communications for the transfer of data to and from the electrical device 800. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 812 may operate in accordance with other wireless protocols in other embodiments. The electrical device 800 may include an antenna 822 to facilitate wireless communications and/or to receive other wireless communications (such as AM or FM radio transmissions).

In some embodiments, the communication component 812 may manage wired communications, such as electrical, optical, or any other suitable communication protocols (e.g., IEEE 802.3 Ethernet standards). As noted above, the communication component 812 may include multiple communication components. For instance, a first communication component 812 may be dedicated to shorter-range wireless communications such as Wi-Fi or Bluetooth, and a second communication component 812 may be dedicated to longer-range wireless communications such as global positioning system (GPS), EDGE, GPRS, CDMA, WiMAX, LTE, EV-DO, or others. In some embodiments, a first communication component 812 may be dedicated to wireless communications, and a second communication component 812 may be dedicated to wired communications.

The electrical device 800 may include battery/power circuitry 814. The battery/power circuitry 814 may include one or more energy storage devices (e.g., batteries or capacitors) and/or circuitry for coupling components of the electrical device 800 to an energy source separate from the electrical device 800 (e.g., AC line power).

The electrical device 800 may include a display device 806 (or corresponding interface circuitry, as discussed above). The display device 806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 800 may include an audio output device 808 (or corresponding interface circuitry, as discussed above). The audio output device 808 may include any embedded or wired or wirelessly connected external device that generates an audible indicator, such speakers, headsets, or earbuds.

The electrical device 800 may include an audio input device 824 (or corresponding interface circuitry, as discussed above). The audio input device 824 may include any embedded or wired or wirelessly connected device that generates a signal representative of a sound, such as microphones, microphone arrays, or digital instruments (e.g., instruments having a musical instrument digital interface (MIDI) output). The electrical device 800 may include a Global Navigation Satellite System (GNSS) device 818 (or corresponding interface circuitry, as discussed above), such as a Global Positioning System (GPS) device. The GNSS device 818 may be in communication with a satellite-based system and may determine a geolocation of the electrical device 800 based on information received from one or more GNSS satellites, as known in the art.

The electrical device 800 may include another output device 810 (or corresponding interface circuitry, as discussed above). Examples of the other output device 810 may include an audio codec, a video codec, a printer, a wired or wireless transmitter for providing information to other devices, or an additional storage device.

The electrical device 800 may include another input device 820 (or corresponding interface circuitry, as discussed above). Examples of the other input device 820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 800 may include a housing 830 and have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 800 may be any other electronic device that processes data. In some embodiments, the electrical device 800 may comprise multiple discrete physical components. Given the range of devices that the electrical device 800 can be manifested as in various embodiments, in some embodiments, the electrical device 800 can be referred to as a computing device or a computing system.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, cither temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Unless otherwise stated, terms or values modified by the word “substantially” include arrangements, orientations, spacings, or positions that vary plus or minus 20% from the meaning of the unmodified term or value. Terms or values modified by the word “about” include values inclusive of 10% less than the term or value to inclusive of 10% greater than the term or value.

As used herein, the term “electronic component” can refer to an active electronic circuit (e.g., processing unit, memory, storage device, FET) or a passive electronic circuit (e.g., resistor, inductor, capacitor).

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (shortened herein to “die”); the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

The following examples pertain to additional embodiments of technologies disclosed herein.

### EXAMPLES

Example 1 is a device, comprising: a substrate having an upper surface, a lower surface, and a first thickness; a deep trench capacitor (DTC) component in the substrate, the DTC component exposed at the upper surface and extending orthogonally downward in the substrate therefrom, wherein the DTC component has a second thickness that is less than the first thickness; and an epoxy material between the lower surface and the DTC component, wherein the epoxy material comprises a particle having a diameter equal to the first thickness minus the second thickness, plus or minus 10%.

Example 2 includes the subject matter of Example 1, wherein the substrate further has therein an electronic integrated circuit.

Example 3 includes the subject matter of Example 2, wherein the electronic integrated circuit is a central processing unit (CPU).

Example 4 includes the subject matter of Example 1, wherein the substrate further has therein a photonic integrated circuit.

Example 5 includes the subject matter of any one of Examples 1-4, wherein the epoxy material is an epoxy resin.

Example 6 includes the subject matter of any one of Examples 1-5, wherein the particle comprises aluminum oxide (Al₂O₃).

Example 7 includes the subject matter of any one of Examples 1-5, wherein the particle comprises an oxide.

Example 8 includes the subject matter of any one of Examples 1-5, wherein the particle is thermally conductive.

Example 9 includes the subject matter of any one of Examples 1-5, wherein the particle is thermally metallic.

Example 10 includes the subject matter of any one of Examples 1-5, wherein the particle is thermally insulating.

Example 11 includes the subject matter of any one of Examples 1-10, further comprising a mold compound sandwiched between the DTC component and the substrate.

Example 12 is a multi-die assembly, comprising: a substrate package having an upper surface, a lower surface, and a first thickness; an integrated circuit (IC) in the substrate package; a deep trench capacitor (DTC) component in the substrate package, the DTC component exposed at the upper surface and extending orthogonally downward in the substrate package therefrom, wherein the DTC component has a second thickness that is less than the first thickness; an epoxy material between the lower surface and the DTC component, wherein the epoxy material comprises a particle having a diameter equal to the first thickness minus the second thickness, plus or minus 10%; and a plurality of conductive contacts on the upper surface of the substrate package and attached to the IC and the DTC component.

Example 13 includes the subject matter of Example 12, further comprising a printed circuit board attached to the plurality of conductive contacts.

Example 14 includes the subject matter of Example 13, further comprising an integrated circuit die attached to the printed circuit board.

Example 15 includes the subject matter of Example 14, further comprising a memory device attached to the printed circuit board.

Example 16 includes the subject matter of Example 15, further comprising a cooling component attached to the substrate package.

Example 17 is a method, comprising: fabricating an integrated circuit on a silicon substrate core; identifying a deep trench capacitor (DTC) component to integrate with the integrated circuit; creating a cavity in the silicon substrate core to accommodate the DTC component; determining a gap magnitude as a function of a thickness of the silicon substrate and a thickness of the DTC component; and selecting an epoxy material with a minimum bond line that matches the gap magnitude.

Example 18 includes the subject matter of Example 17, further comprising: attaching a temporary carrier to a lower surface of the silicon substrate core; dispensing the epoxy material in the cavity on the temporary carrier; and placing the DTC component on the epoxy material in the cavity.

Example 19 includes the subject matter of Example 18, wherein selecting the epoxy material with the minimum bond line includes selecting a particle type that has a diameter equal to the gap magnitude, plus or minus 10%.

Example 20 includes the subject matter of Example 18 wherein selecting the epoxy material with the minimum bond line includes selecting a particle type that is an oxide.

What is claimed is:

1. A device, comprising:
a first substrate having an upper surface, a lower surface, and a first thickness;
a capacitor component in the first substrate, the capacitor component comprising a second substrate and a second thickness that is less than the first thickness, the capacitor component comprises a trench formed in the second substrate that extends orthogonally downward from the upper surface with an aspect ratio of at least 10, wherein the capacitor component comprises metal layers that conformally follow the trench; and
an insulating material between the lower surface and the second substrate of the capacitor component, wherein the insulating material comprises a particle having a diameter equal to the first thickness minus the second thickness, plus or minus 20%.

2. The device of claim 1, wherein the first substrate further has therein an electronic integrated circuit.

3. The device of claim 2, wherein the electronic integrated circuit is a central processing unit (CPU).

4. The device of claim 1, wherein the first substrate further has therein a photonic integrated circuit.

5. The device of claim 1, wherein the insulating material is an epoxy resin.

6. The device of claim 1, wherein the particle comprises aluminum oxide (Al₂O₃).

7. The device of claim 1, wherein the particle comprises an oxide.

8. The device of claim 1, wherein the particle is thermally conductive.

9. The device of claim 1, wherein the particle is thermally metallic.

10. The device of claim 1, wherein the particle is thermally insulating.

11. The device of claim 1, further comprising a mold compound sandwiched between the capacitor component and the first substrate.

12. A multi-die assembly, comprising:
a substrate package having an upper surface, a lower surface, and a first thickness;
an integrated circuit (IC) in the substrate package;
a capacitor component in the substrate package, the capacitor component exposed at the upper surface and comprising a trench that extends orthogonally downward in a second substrate therefrom, wherein the capacitor component has a second thickness that is less than the first thickness;
an insulating material between the lower surface and the second substrate of the capacitor component, wherein the insulating material comprises a particle having a diameter equal to the first thickness minus the second thickness, plus or minus 20%; and
a plurality of conductive contacts on the upper surface of the substrate package and attached to the IC and the capacitor component.

13. The multi-die assembly of claim 12, further comprising a printed circuit board attached to the plurality of conductive contacts.

14. The multi-die assembly of claim 13, further comprising an integrated circuit die attached to the printed circuit board.

15. The multi-die assembly of claim 14, further comprising a memory device attached to the printed circuit board.

16. The multi-die assembly of claim 15, further comprising a cooling component attached to the substrate package.

17. A method, comprising:
fabricating an integrated circuit on a silicon substrate;
identifying a capacitor component with a trench capacitor to integrate with the integrated circuit;
creating a cavity in the silicon substrate to accommodate the capacitor component;
determining a magnitude of a gap defined as a difference between a thickness of the silicon substrate and a thickness of the capacitor component; and
selecting an insulating material with a minimum bond line that matches the magnitude.

18. The method of claim 17, further comprising:
attaching a temporary carrier to a lower surface of the silicon substrate;
dispensing the insulating material in the cavity on the temporary carrier; and
placing the capacitor component on the insulating material in the cavity.

19. The method of claim 18, wherein selecting the insulating material with the minimum bond line includes selecting a particle type that has a diameter equal to the magnitude, plus or minus 20%.

20. The method of claim 18 wherein selecting the insulating material with the minimum bond line includes selecting a particle type that is an oxide.
